(19) United States
(12) Patent Application Publication
(10) Pub. No.: US 2025/0012880 A1
(43) Pub. Date: Jan. 9, 2025

(54) Super Resolution for a Non-Rectangular Acquisition of Magnetic Resonance Raw Data

(71) Applicant: Siemens Healthineers AG, Forchheim (DE)

(72) Inventor: Marcel Dominik Nickel, Herzogenaurach (DE)

(73) Assignee: Siemens Healthineers AG, Forchheim (DE)

(21) Appl. No.: 18/763,153

(22) Filed: Jul. 3, 2024

(30) Foreign Application Priority Data
Jul. 5, 2023 (DE) 10 2023 206 366.2

(51) Int. Cl. G01R 33/48; G01R 33/56; G01R 33/561

(52) U.S. Cl. CPC G01R 33/4824; G01R 33/5608; G01R 33/5611

(57) ABSTRACT

A method and device for generating MRI data with increased resolution is described. In the method, k-space data is sampled with a non-rectangular sampling pattern. A non-rectangular sampling region of a Cartesian k-space is sampled and a complementary region (KB) of the Cartesian k-space is not sampled. First MR image data is reconstructed based on the sampled k-space data. Second MR image data with an increased resolution compared to a resolution of the reconstructed first MR image data is generated by applying a supplementing method adapted to supplement the reconstructed first MR image data with image information which, transformed into the Fourier domain of the reconstructed first MR image data, is associated with the complementary region determined from the k-space-sampling.

### CROSS REFERENCE TO RELATED APPLICATIONS

This patent application claims priority to German Patent Application No. 10 2023 206 366.2, filed Jul. 5, 2023, which is incorporated herein by reference in its entirety.

### BACKGROUND

### Field

The disclosure relates to a method for generating magnetic resonance image data of an examination object with increased resolution, wherein the magnetic resonance raw data is acquired by a non-rectangular acquisition. In addition, the disclosure relates to a method for training an AI-based model for supplementing magnetic resonance image data with image information. The disclosure also relates to an image data-generating facility. Furthermore, the disclosure relates to a magnetic resonance imaging system.

### Related Art

Imaging systems, which are based on a method of magnetic resonance measurement, in particular of nuclear spins, what are known as magnetic resonance tomographs, have successfully established and proven themselves by way of diverse applications. With this type of image acquisition a static basic magnetic field B₀, which serves for initial orientation and homogenization of magnetic dipoles to be examined, is usually overlaid with a fast-switched magnetic field, what is known as a gradient field, for spatial resolution of the imaging signal. To determine material properties of an examination object to be mapped, the dephasing or relaxation time after a deflection of the magnetization from the initial orientation is ascertained, so different material-typical relaxation mechanisms or relaxation times can be identified. The deflection usually takes place due to a number of RF pulses (the abbreviation RF stands for radio frequency), also referred to as excitation pulses, and the spatial resolution is based on a temporally defined manipulation of the deflected magnetization with the aid of the gradient field in what is known as a measuring sequence or actuation sequence which defines an exact temporal sequence of RF pulses, the change in the gradient field (by emitting a switching sequence of gradient pulses) and the acquisition of measured values. Typically, there is an association between measured magnetization—from which said material properties can be derived—and a spatial coordinate of the measured magnetization in the spatial domain in which the examination object is arranged, with the aid of an intermediate step. Acquired magnetic resonance raw data, also referred to as k-space data, is arranged at readout points in what is known as the “k-space” in this intermediate step, wherein the coordinates of the k-space are encoded as a function of the gradient field. The amount of magnetization (in particular the transverse magnetization in a plane transverse to the previously described basic magnetic field) at a particular location of the examination object can be ascertained from the data of the readout point with the aid of a Fourier transform, which calculates a signal strength of the signal in the spatial domain from a signal strength (amount of magnetization) which is associated with a particular frequency (the spatial frequency) or phase position.

The k-space is frequently only partially sampled, however, in order to save time. The reduced sampling of the k-space results in a reduction in the image information reconstructed on the basis of the sampled k-space data, however, in particular in a reduction in the image resolution. To compensate for this loss of information, there are methods with which the undersampling is compensated. Methods of this kind can be connected with an augmenting of the k-space data as well as being targeted at a direct increase in the resolution in the image data domain.

The super resolution and the partial Fourier reconstruction are means for improving the image quality in magnetic resonance imaging within the meaning of an improvement in the image resolution in the image data domain.

Super resolution may be achieved by way of machine learning, with the aim being to increase the resolution of an image frequently by fourfold or more. Super resolution has already been achieved for Cartesian sequences. However, there is currently no solution to elliptical scanning and non-Cartesian trajectories such as BLADE/PROPELLER (PROPELLER is an acronym for “Periodically Rotated Overlapping ParallEL Lines with Enhanced Reconstruction”, uppercase letters are part of the acronym), radially or helically.

K-space filters are typically used in the case of elliptical scanning for BLADE (radial sampling sequence for reducing movement artifacts) and also for other non-Cartesian acquisitions in order to avoid truncation artifacts such as Gibbs ringing. However, no deep-learning solutions are currently used for these non-Cartesian sampling methods.

The performance of super resolution networks in MRI, which are trained for Cartesian acquisitions, depends to a large extent on the coverage of the k-space. Deep Resolve Sharp is trained on fully sampled acquisitions and the performance is greatly reduced if the reconstruction of the input image includes a zerofill (typically with low sharpness).

In the case of partial Fourier acquisitions, it has been observed that deep-learning-based algorithms can learn to reproduce non-measured data of the asymmetric acquisition, similar to conventional partial Fourier algorithms, but also for applications in which conventional algorithms fail. Exemplary results were presented in the document below:

Wessling D, Herrmann J, Afat S, Nickel D, Almansour H, Keller G, Othman A E, Brendlin A S, Gassenmaier S. Application of a Deep Learning Algorithm for Combined Super-Resolution and Partial Fourier Reconstruction Including Time Reduction in T1-Weighted Precontrast and Postcontrast Gradient Echo Imaging of Abdominopelvic MR Imaging. Diagnostics (Basel). 2022 Sep. 29; 12(10): 2370. doi: 10.3390/diagnostics12102370. PMID: 36292057; PMCID: PMC9600324.

Similar results were achieved for diffusion-weighted imaging. However, said approaches of super resolution are limited to imaging with Cartesian or rectangular sampling patterns.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a diagram which illustrates a magnetic resonance image in the image data domain and associated Fourier domain data in the Fourier domain, according to the disclosure.

FIG. 2 is a flowchart of a method for generating magnetic resonance image data of an examination object with increased resolution, according to the disclosure.

FIG. 3 is a diagram which illustrates an architecture of an artificial neuronal network with which the method illustrated in FIG. 2 can be implemented.

FIG. 4 is a flowchart of a method for training an AI-based model for supplementing magnetic resonance image data, according to the disclosure.

FIG. 5 shows an image data-generator according to the disclosure.

FIG. 6 shows a schematic representation of a correlation between a field of view and a parameterization of an ellipsoidal sampling pattern in the k-space, according to the disclosure.

FIG. 7 shows a schematic representation of a generation in sections of highly resolved magnetic resonance image data by acquiring k-space data with a circular sampling pattern, according to the disclosure.

FIG. 8 shows a magnetic resonance imaging system, according to the disclosure.

The exemplary embodiments of the present disclosure will be described with reference to the accompanying drawings. Elements, features and components that are identical, functionally identical and have the same effect are—insofar as is not stated otherwise-respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to provide magnetic resonance imaging with improved image quality, including in the case of non-rectangular partial sampling of the k-space.

This is other objects of the disclosure are realized by, for example, a method for generating magnetic resonance image data of an examination object with increased resolution, a method for training a trained AI-based model for a method for supplementing magnetic resonance image data with image information, an image data-generating facility, and by a magnetic resonance imaging system.

In the inventive method for generating magnetic resonance image data of an examination object with increased resolution, k-space data is sampled with a non-rectangular sampling pattern. A non-rectangular sampling region of a Cartesian k-space is sampled and a complementary region of the Cartesian k-space is not sampled. A non-rectangular sampling pattern should be taken to mean a sampling pattern in which a k-space trajectory is followed which at least partially does not run parallel to the coordinate axes of a Cartesian coordinate system. It should also be considered that such a Cartesian coordinate system can be rotated. In particular, curvilinearly running trajectories or non-parallel, in particular radially running, trajectories are non-rectangular.

Furthermore, first magnetic resonance image data is reconstructed on the basis of the sampled k-space data. The first magnetic resonance image data is generated, as is customary, on the basis of a Fourier transform of the k-space into the image data domain.

Finally, second magnetic resonance image data is generated with an increased resolution compared to a resolution of the reconstructed first magnetic resonance image data by applying a method which is based on an AI-based model adjusted to the non-rectangular sampling pattern and is embodied to supplement the reconstructed first magnetic resonance image data with image information which, transformed into the Fourier domain, or its associated data in the Fourier domain, is associated with the reconstructed first magnetic resonance image data, is associated with the complementary region determined from the k-space sampling.

The k-space relates to the respective space in which the measured multi-channel raw data is sampled or measured. The Fourier domain is the domain in which the “synthetic” raw data arranged by way of a Fourier transform of the channel-combined image is arranged. A difference between k-space and Fourier domain is significant when the k-space data is sampled by a multi-coil system with a plurality of channels. In this case the k-space therefore has one separate k-space per channel in which k-space data is sampled according to a specified pulse sequence or trajectory. In the Fourier domain, by contrast, the transformed data of an overall image, which is based on a reconstruction on the basis of sampled k-space data of all channels of the relevant multi-coil system, is represented together. Nevertheless, said sampling regions in the k-space, i.e. the non-rectangular sampling region and the complementary region, can also be found in in the Fourier domain again, wherein they accordingly result from a Fourier transform of the respective image data which was reconstructed by sampling the respective sampling regions in the k-space.

“Magnetic resonance image data”, which is associated with the complementary region, should be taken to mean that image information in the form of a higher resolution is gained by way of an additional item of image information which, transformed by way of Fourier transform into the Fourier domain, is arranged in the complementary region as Fourier domain data.

An AI-based model adjusted to the non-rectangular sampling pattern should be taken to mean an AI-based model which was trained by way of image data which was generated by sampling a non-rectangular sampling region of the k-space with a non-rectangular sampling pattern. The additional items of image information are associated with Fourier domain data which lie outside of the sampling region taken up by the trajectory following the non-rectangular sampling pattern. The items of information ascertained by the non-rectangular acquisition of k-space data are therefore accepted unchanged in the second magnetic resonance image data with increased resolution. It is crucial that the AI-based model, after its training by way of first magnetic resonance image data, which was generated by sampling the k-space by applying a particular non-rectangular sampling pattern, is also applied to such first magnetic resonance image data. It is precisely in such a case that it is possible for the second magnetic resonance image data to be generated by supplementing the first magnetic resonance image data with image information, which was obtained by Fourier transform of the k-space data of the complementary region.

Advantageously, the resolution of magnetic resonance image data, which was obtained by sampling the k-space with a non-rectangular sampling pattern, can be increased. The training of the AI-based model used for increasing the resolution is concentrated on image data which was obtained by applying this specific non-rectangular sampling pattern. It should be noted that the geometry of the sampling region of the k-space, which was sampled for reconstruction of the magnetic resonance image data of the training data, is consistent with the geometry of the sampling region of the k-space, which was sampled for generating the first magnetic resonance image data. A particularly effective and exact increase in the resolution of the first magnetic resonance image data is achieved in this way, with image artifacts, in particular, also being reduced. As explained in detail later, there are also possibilities, however, for a trained AI-based model to continue to be used on a change in the field of view, and therewith a change in the spacings of the sampling points in the k-space, without more training.

In the inventive method for training an AI-based model for supplementing magnetic resonance image data with image information, labeled training data, which has input data and validated results data, is generated. The validated results data comprises reconstructed image data, which was reconstructed on the basis of raw data, which was obtained by complete sampling of a Cartesian k-space, and the input data comprises image data, which was reconstructed on the basis of a subset of the raw data or k-space data, wherein the subset of the k-space data is associated with a non-rectangular sampling pattern region of the k-space which was generated by setting the k-space data outside of the sampling region to the value 0. “Complete” sampling of the k-space should be taken to mean sampling of a rectangular k-space which comprises the two portions defined above, i.e. the non-rectangular sampling region and the complementary region.

The AI-based model to be trained is applied with the method for supplementing magnetic resonance image data with image information to the labeled input data, with results data being generated.

The AI-based model is then adapted on the basis of the results data and the validated results data.

In an exemplary embodiment, the trained AI-based model is finally provided for the method for generating magnetic resonance image data of an examination object with increased resolution. The training method advantageously generates an AI-based model adjusted to a particular sampling pattern, with which model the resolution of magnetic resonance image data, which can be improved on the basis of k-space data which was acquired with such a sampling pattern.

The inventive image data-generating facility (image data generator) has an input interface for receiving sampled k-space data with a non-rectangular sampling pattern, wherein a non-rectangular sampling region of a Cartesian k-space is sampled and a complementary region of the Cartesian k-space is not sampled. The image data generator may also be referred to as an image data processor.

Part of the inventive image data-generating facility is a reconstruction unit for reconstructing first magnetic resonance image data on the basis of the sampled k-space data.

The inventive image data-generating facility has, in particular, an image data-generating unit for generating second magnetic resonance image data with increased resolution compared to a resolution of the reconstructed first magnetic resonance image data by applying a method which is based on an AI-based model and is embodied to supplement the reconstructed first magnetic resonance image data with image information which, transformed into the Fourier domain of the reconstructed first magnetic resonance image data, is associated with the complementary region determined from the k-space-sampling. The inventive image data generator/processor shares the advantages of the inventive method for generating magnetic resonance image data of an examination object with increased resolution.

The inventive magnetic resonance imaging system has the inventive image data-generating facility. The inventive magnetic resonance imaging system shares the advantages of the inventive method for generating magnetic resonance image data of an examination object with increased resolution.

The inventive computer program product has program code segments with which all steps of the inventive method for generating magnetic resonance image data of an examination object with increased resolution and the method for training an AI-based model for a method for supplementing magnetic resonance image data with image information, can be executed when the program is executed in a magnetic resonance imaging system or a control facility (controller) of such a magnetic resonance imaging system.

An implementation largely in terms of software has the advantage that existing magnetic resonance imaging systems or their control facilities can be easily retrofitted by way of a software update in order to work inventively.

The majority of the previously mentioned components of the inventive image data-generating facility can be implemented wholly or partially in the form of software modules in a processor of a corresponding computing system, for example by a controller of a magnetic resonance imaging system or a computer which is used for controlling such a system. An implementation largely in terms of software has the advantage that even previously used computing systems can be easily retrofitted by way of a software update in order to work inventively. In this regard the object is also achieved by a corresponding computer program product with a computer program which can be loaded directly into a computing system, with program segments in order to execute the steps of the inventive method for generating magnetic resonance image data of an examination object with increased resolution and the method for training an AI-based model for supplementing magnetic resonance image data with image information when the program is executed in the computing system. Apart from the computer program, such a computer program product can potentially comprise additional component parts, such as documentation and/or additional components, also hardware components, such as hardware keys (dongles, etc.) in order to use the software.

A computer-readable medium, for example a memory stick, a hard disk or another transportable or permanently installed data carrier, on which the program segments of the computer program, which can be read in and executed by a computing system, are stored, can serve for transportation to the computing system or to the controller and/or for storage on or in the computing system or the controller. The computing system can have, for example, one or more cooperating microprocessor(s) or the like for this purpose.

The various features of different exemplary embodiments can also be combined within the framework of the disclosure to form new exemplary embodiments.

In an exemplary embodiment of the inventive method for generating magnetic resonance image data of an examination object with increased resolution, the increased resolution may be achieved by supplementing magnetic resonance image data which is associated with higher frequencies in the Fourier domain and in the k-space. Higher frequencies are customarily associated with regions located further out in the k-space. The raw data arranged in this complementary region comprises items of information on whose basis image data with higher resolution can be obtained. By contrast, the raw data located in the center of the k-space serves for ascertaining the underlying contours of an examination object to be mapped with lower resolution.

In an exemplary embodiment of the inventive method for generating magnetic resonance image data of an examination object, the non-rectangular sampling pattern comprises one of the following sampling pattern types:
radial sampling,
elliptical sampling,
helical sampling,
BLADE sampling or PROPELLER sampling.

In the case of radial sampling, the k-space is sampled by a radial k-space-trajectory which is composed of a plurality of radial profiles which each run through the middle of the k-space. Radial trajectories are less susceptible to movement artifacts and are therefore frequently used for recording dynamic physiological processes. Furthermore, radial trajectories are more robust compared to Cartesian trajectories with respect to an incomplete rotation scan which is used in time-resolved imaging in order to improve the temporal resolution.

The PROPELLER technique was developed at the end of the 1990s as a method for reducing movement. The basic idea consisted in sampling the k-space in a rotational manner with the aid of a series of radially directed strips or “rotor blades”.

Each “rotor blade” is composed of a plurality of parallel phase-encoded lines which can be acquired with fast spin echo or gradient echo methods. In common practice eight to 32 rotor blade-lines are captured in a single acquisition. The rotor blades are then rotated about a small angle (10° bis) 20°, with a second dataset being acquired. The process is continued until image data has been collected from the entire k-space circle.

The PROPELLER trajectory through the k-space offers some unique advantages. The center of the k-space (which contains the highest signal amplitude and contributes the most to the image contrast) is oversampled, and this means that the signal-to-noise ratio and the contrast-to-noise ratio are high. The oversampling in this region also provides for redundancy of the items of information, and this means that the data for each new blade can be compared for consistency reasons with the data of earlier blades. If the patient moves between the acquisition of k-space data of different rotor blades, the data for the next rotor blade can be corrected (or even completely discarded) depending on how anomalous its central items of information appear.

In an exemplary embodiment, generating magnetic resonance image data with increased resolution compared to a resolution of the reconstructed magnetic resonance image data comprises a partial step for generating data consistency.

Firstly, preliminary second magnetic resonance imaging data is generated by the method which is based on an AI-based model.

For generating the data consistency, the preliminary second magnetic resonance image data is transformed into the Fourier domain, with Fourier domain data associated with the preliminary second magnetic resonance image data being generated in the process. Furthermore, modified Fourier domain data is generated, with the Fourier domain data associated with the preliminary second magnetic resonance image data within the non-rectangular sampling region being modified by a projection of the sampled k-space data or Fourier domain data associated with the first magnetic resonance image data to the Fourier domain data associated with the second magnetic resonance image data. In this “projection” the first magnetic resonance image data is transformed into the Fourier domain, with Fourier domain data associated with the sampled k-space data being generated. This Fourier domain data then replaces the Fourier domain data associated with the second magnetic resonance image data in a portion of the Fourier domain or is combined with it in the portion. The thus modified Fourier domain data is finally transformed into the image data domain, with data-consistent second magnetic resonance image data being generated. Advantageously, the items of image information of the first magnetic resonance image data are also accepted in the second magnetic resonance image data.

Most In an exemplary embodiment, a dedicated model for the specifically used sampling pattern type is utilized as the AI-based model in the inventive method. It is crucial for the reduction of artifacts and good data consistency that the AI-based model is trained by way of training data generated for a specific sampling pattern type. Advantageously, the image quality of the second magnetic resonance image data is particularly good due to applying a dedicated model to the first magnetic resonance image data.

In an exemplary embodiment of the inventive method for generating magnetic resonance image data of an examination object with increased resolution in which magnetic resonance raw data is acquired by a non-Cartesian acquisition, a plurality of image portions formed by a subset of the magnetic resonance image data is defined as a function of the geometry of the sampling pattern and the AI-based model is applied to the respective image portions and the highly resolved magnetic resonance image data generated on the basis of the magnetic resonance image data of the respective image portions is combined to form a highly resolved overall image. Advantageously, the AI-based model can be applied to magnetic resonance image data, which is associated with images with a different geometry. It should be noted in this connection that the geometry of the sampling pattern is dependent on the image geometry or the geometry of the field of view. To be able to apply an AI-based model, which is trained in a particular geometry of a sampling pattern, to different geometries of a field of view, the field of view is quasi divided into possibly mutually overlapping portions whose geometry is consistent with the sampling pattern of the AI-based model. The highly resolved partial images or image portions generated by the AI-based model are then put together to form a highly resolved overall image. Advantageously, the field of application of an AI-based model, which is trained in a particular geometry of a sampling pattern, is expanded to different geometries of a field of view.

In an exemplary embodiment, during the procedure of putting together the partial images or image portions to form a highly resolved overall image, the highly resolved overall image may be put together or combined by way of addition, based on a fade-out, of the highly resolved magnetic resonance image data from mutually overlapping sections of the respective image portions. Such a “fade-out” comprises a function, gradually decreasing toward the edges of the image, between the values 0 and 1, which is applied to edge regions of mutually overlapping image portions and with which a sliding transition between the image portions is generated. Advantageously, an abrupt transition between the image portions is avoided and the image quality of the highly resolved overall image is thus improved.

In an exemplary embodiment, k-space data is sampled in the framework of undersampling with a non-rectangular sampling pattern with a multi-coil system in the inventive method for generating magnetic resonance image data of an examination object. Experiments have proved that AI-based models trained in non-rectangular trajectories also efficiently increase the resolution of image data which is based on k-space data which was acquired with a multi-coil system.

If an imaging method for simultaneously reading out a plurality of slices is used in the inventive method, then the number N of slices to be read out simultaneously is two in an embodiment of the method which can be particularly effectively implemented. Advantageously, the acquisition time can be reduced further by simultaneously reading out a plurality of slices, so a higher patient throughput and improved comfort is achieved for the patients to be examined.

Alternatively, the number N of slices to be simultaneously read out can also be three. Basically, it would be optimal to simultaneously read out as many slices as possible. However, the number of slices to be simultaneously read out is limited by the following circumstances: the energy supplied to the patient per pulse is proportional to the number of slices N. The energy supply permitted per time is limited, however. In addition, separation is all the more difficult in the image reconstruction, the more slices that are simultaneously read out since the noise increases in the separated images. This increase does not behave linearly. Therefore, in practice, it is only possible to read out a few slices simultaneously.

In an exemplary embodiment of the inventive method for training an AI-based model for a method for supplementing magnetic resonance image data with image information for generating magnetic resonance image data with increased resolution, the model comprises a conventional super resolution network. Super resolution networks are used to increase the resolution of image data by way of a modification of the image data in the image data domain.

In an exemplary embodiment the input data and/or results data may comprise phase images or complex-valued images, which may include real and imaginary parts as the different channels, in the inventive method for training an AI-based model for a method for supplementing magnetic resonance image data with image information.

In neural networks, images are treated as tensors. Such tensors typically have the following dimensions: batch, channel, depth, height, width (abbreviated to BCDHW). The last three are spatial dimensions. Channel is a dimension, with channels also correlating with one another by way of convolutions. In addition, not all AI frameworks can handle complex numbers (a few years ago this was not possible at all, but it is slowly establishing itself). It is therefore customary to regard complex-valued images as tensors with two channels. The real part and the imaginary part are “stacked” (arranged in a batch structure).

In an exemplary embodiment, the AI-based model comprises a hard projection for producing data consistency, so only frequencies outside of the sampling region can be changed. In this connection a “hard projection” should be taken to mean that in the Fourier domain the Fourier domain data, which is generated by a Fourier transform of the first magnetic resonance image data into the Fourier domain, is fully accepted for the second magnetic resonance image data and the additional image information is limited to data whose associated Fourier domain data lies outside of this Fourier domain region, i.e. lies outside of the Fourier domain region which is covered by Fourier domain data which is generated by a Fourier transform of the first magnetic resonance image data into the Fourier domain.

Metaphorically speaking, a type of mask is used with which the low-frequency Fourier domain data is removed from the preliminary second magnetic resonance image data and is replaced by the Fourier domain data associated with the first magnetic resonance image data. The thus modified Fourier domain data is then transformed into the image data domain, with second magnetic resonance image data with increased resolution being produced.

Alternatively, the AI-based model comprises a soft projection, so frequencies within the sampling region are shifted in the direction of the frequencies in the input image data. A soft projection should be taken to mean a projection in which the low-frequency Fourier domain data is only partially removed from the preliminary second magnetic resonance image data in the Fourier domain and instead the Fourier domain data, which is associated with the first magnetic resonance image data, and the Fourier domain data, which is associated with the second magnetic resonance image data, are collated in the inner region of the Fourier domain which is covered by Fourier domain data which is generated by transformation of the first magnetic resonance image data into the Fourier domain.

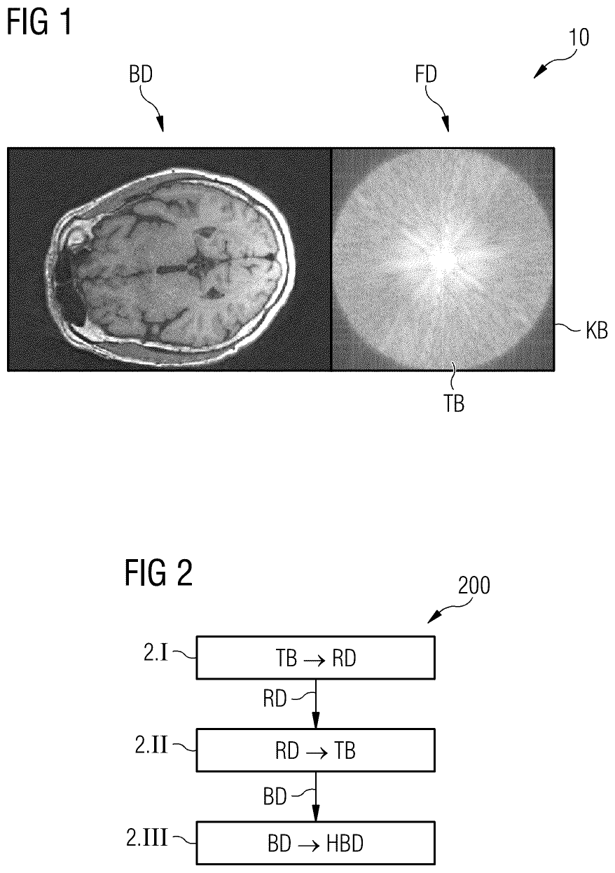

FIG. 1 shows a diagram 10 which illustrates magnetic resonance image data BD in the image data domain (see left of FIG. 1) and Fourier domain data FD associated with the magnetic resonance image data BD (see right of FIG. 1) in the Fourier domain. The left side of the diagram 10 shows image data BD in the image data domain of a skull of a patient and the right side of the diagram 10 shows corresponding Fourier domain data FD of the image data BD shown on the left side. The Fourier domain data FD is generated by a Fourier transform of the image data BD into the Fourier domain. The Fourier domain data FD shows a circular region. A spatial domain in the k-space corresponding to the Fourier domain is sampled, for example, by a radial trajectory. As shown on the right side of FIG. 1, the portion TB of the Fourier domain occupied due to transformation of the image data BD into the Fourier domain does not correspond to the entire Fourier domain represented as a square, but only a circular portion TB thereof. A complementary region KB forms the region of the Fourier domain which is not occupied by the Fourier domain data FD which is associated with the image data BD.

FIG. 2 shows a flowchart 200 which illustrates a method for generating magnetic resonance image data HBD of an examination object with increased resolution according to an exemplary embodiment of the disclosure.

In step 2.I, k-space data RD is sampled in the framework of an undersampling with a non-rectangular sampling pattern, as is illustrated, albeit in the Fourier domain and not in the k-space, for example, in FIG. 1 on the right side of the diagram 10. As illustrated in FIG. 1, it is not the entire k-space represented as a square that is sampled but only a circular portion TB thereof. A complementary region KB of the k-space remains unsampled, by contrast.

In step 2.II, magnetic resonance image data BD is reconstructed on the basis of the undersampled k-space data RD of the circular portion TB.

In step 2.III, magnetic resonance image data HBD with an increased resolution compared to a resolution of the reconstructed magnetic resonance image data BD is generated by applying an AI-based model to the reconstructed magnetic resonance image data BD.

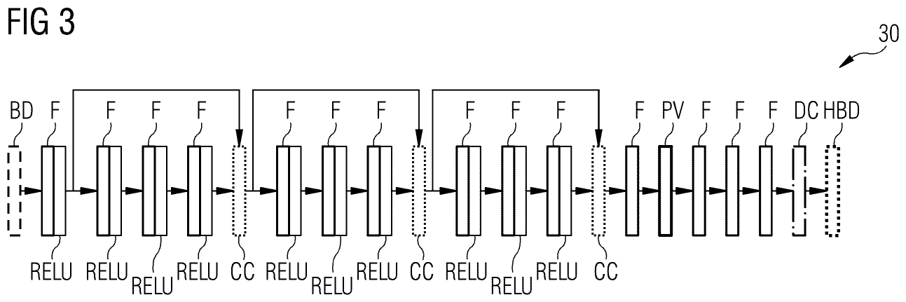

FIG. 3 shows a diagram 30 which illustrates an architecture of an artificial neural network with which the method illustrated in FIG. 2 can be implemented. The neural network starts with an input of magnetic resonance image data BD. The magnetic resonance image data BD is processed in 10 slices in total which each have a convolution function F and an activation function RELU. Following the three or four of these 10 slices in each case, a concatenation CC of the intermediate results is carried out in each case and hereinafter a convolution F is carried out again. A pixel interleaving PV then takes place, followed by three further filterings F or convolutions. Lastly, data consistency DC is generated. Finally, magnetic resonance image data HBD with increased resolution is output.

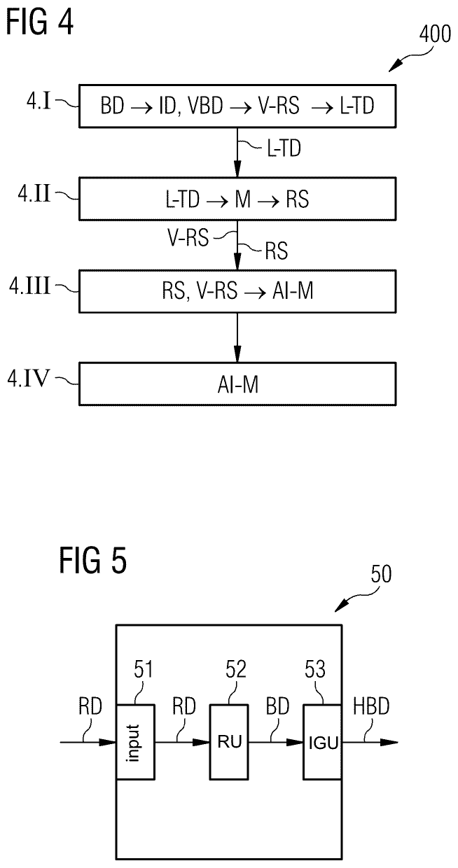

FIG. 4 shows a flowchart 400 which illustrates a method for training an AI-based model M for a method for supplementing magnetic resonance image data BD with image information.

In step 4.I, labeled training data L-TD is generated which has input data ID and validated results data V-RS. The validated results data V-RS has image data VBD which was reconstructed by complete sampling of the k-space. The input data ID has image data BD which was reconstructed on the basis of k-space data which was acquired with a non-rectangular sampling pattern. This k-space data was generated by setting the frequencies of the k-space data, associated with the image data VBD of the validated results data V-RS, outside of the sampling region to zero.

In step 4.II, the AI-based model M to be trained is applied to the labeled input data L-ID, with results data RS being generated.

In step 4.III, the AI-based model M is adapted on the basis of the results data RS and the validated results data V-RS.

In step 4.IV, the trained AI-based model AI-M is output. Steps 4.II to 4.III can be repeated more frequently with the respectively adapted model AI-M as the AI-based model M to be trained in order to further adjust the adapted model AI-M. The thus implemented iteration is ended when the adapted model AI-M has reached a predetermined quality criterion. For example, a result vector RS from the validated results data V-RS deviates by less than a predetermined threshold value from a result vector of the validated results data V-RS so the quality criterion is met. The deviation can be ascertained, for example, by calculating a vector standard of the difference in the two vectors.

FIG. 5 illustrates a schematic representation of an image data-generating facility (image data generator/image data processor) 50 according to an exemplary embodiment of the disclosure.

The image data-generating facility 50 may comprise an input interface 51 for receiving k-space data RD which was sampled in the framework of an undersampling with a non-rectangular sampling pattern.

Furthermore, the control facility (controller) may comprise a reconstruction unit (reconstructor) 52 for reconstructing first magnetic resonance image data BD on the basis of the undersampled k-space data RD.

An image data-generating unit (image data generator/image data processor) 53 for generating second magnetic resonance image data HBD with increased resolution compared to a resolution of the reconstructed magnetic resonance image data BD by applying an AI-based model to the reconstructed magnetic resonance image data BD is also part of the image data-generating facility 50.

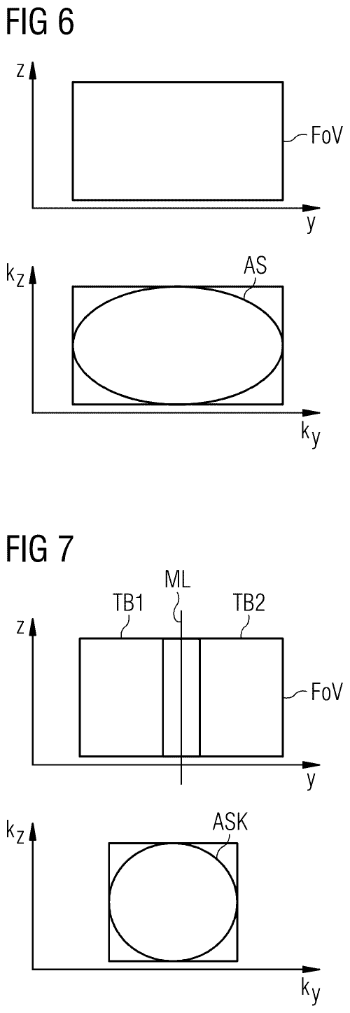

FIG. 6 illustrates a schematic representation of a correlation between a field of view FoV, i.e. an examination region to be mapped, and a parameterization of an ellipsoidal sampling pattern AS in the k-space. FIG. 6 represents a rectangular field of view FOV in the image data domain. An elliptical sampling pattern AS corresponding to this field of view FoV is embodied in the k-space. That is to say, the eccentricity of the ellipsis of the elliptical sampling pattern AS is matched to the dimensions of the field of view FoV.

FIG. 7 shows a schematic representation of a generation in sections of highly resolved magnetic resonance image data by acquiring von k-space data with a circular sampling pattern ASK. While the field of view FoV has the same dimensions as that shown in FIG. 6, a circular sampling pattern ASK instead of an ellipsoidal sampling pattern AS is accordingly used for acquiring k-space data. So, the process of increasing the resolution functions correctly despite the different geometry of the sampling and the field of view FoV, the field of view FoV in the embodiment shown in FIG. 7 is divided into mutually overlapping square portions TB1, TB2. The method for generating magnetic resonance image data HBD with increased resolution is applied separately to the two square portions TB1, TB2 in this case, and these each extend in FIG. 7 beyond the vertical center line ML of the field of view FoV. The mutually overlapping partial images TB1, TB2 produced by applying this method are then merged with increased resolution, with the overlapping region being added to or overlaid with what is known as a “fade-out”.

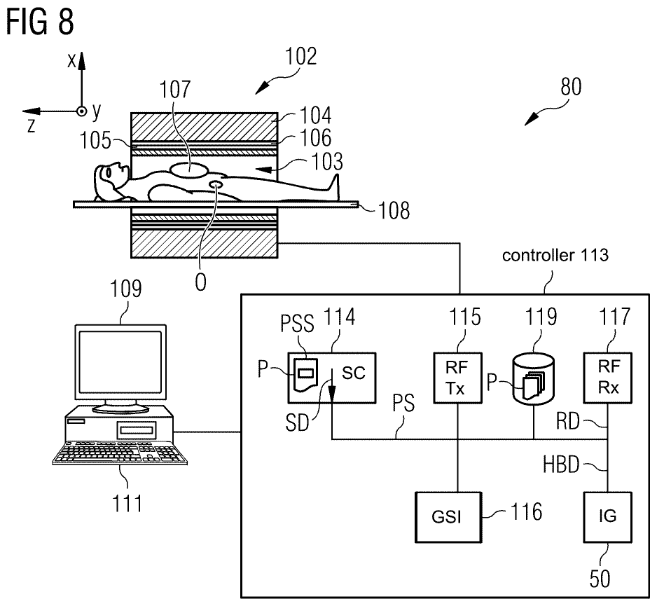

FIG. 8 grossly schematically represents an inventive magnetic resonance system 80 (hereinafter called “MR system” for short). Firstly, it comprises the actual magnetic resonance scanner 102 with an examination space 103 or patient tunnel into which a patient O, or here a patient or test person, lying on a couch 108 can be moved, in the body of which patient a particular organ to be mapped, for example, is located.

The magnetic resonance scanner 102 is customarily fitted with a basic field magnet system 104, a gradient system 106 and an RF transmitting antenna system 105 and an RF receiving antenna system 107. In the represented exemplary embodiment, the RF-transmitting antenna system 105 is a body coil permanently installed in the magnetic resonance scanner 102, whereas the RF-receiving antenna system 107 is composed of local coils to be arranged on the patient or test person (symbolized in FIG. 8 by just a single local coil). Basically, however, the body coil 105 can also be used as an RF receiving antenna system and the local coils 107 as an RF transmitting antenna system if these coils can be respectively switched into different modes of operation.

The MR system 80 may include a central control facility (controller) 113 which is adapted to control the MR system 80. The controller 113 may comprise a sequence controller 114 for controlling the pulse sequence. The temporal sequence of radio frequency pulses (RF pulses) and gradient pulses is controlled as a function of a selected imaging sequence PS according to a pulse sequence pattern PSS with this unit. Such an imaging sequence PS or the pulse sequence pattern PSS underlying the imaging sequence PS can be specified, for example, within a measuring or control protocol P. Customarily various control protocols P for different measurements are stored in a memory 119 and can be selected by an operator (and potentially changed as needed) and then be used for carrying out the measurement.

In order to output the individual RF pulses the central controller 113 may include a radio frequency (RF) transmitting facility (RF transmitter) 115 which generates the RF pulses, amplifies them and feeds then into the RF transmitting antenna system 105 via a suitable interface (not represented in detail). In order to control the gradient coils of the gradient system 106 the controller 113 has a gradient system interface 116. The sequence controller 114 communicates in an appropriate manner, for example by emitting sequence control data SD, with the radio frequency transmitting facility 115 and the gradient system interface 116 in order to emit the pulse sequences PS. The controller 113 may include a radio frequency (RF) receiving facility (RF receiver) 117 (likewise communicating with the sequence controller 114 in an appropriate manner) in order to acquire magnetic resonance signals received in a coordinated manner from the RF transmitting antenna system 107.

The central controller 113 may also comprise an inventive image data-generating facility (image data generator/image data processor) 50 which has the construction illustrated in detail in FIG. 5.

A reconstruction unit (reconstructor) 52 (see FIG. 5), which accepts the acquired data, after demodulation and digitalization, as raw data or k-space data RD and reconstructs magnetic resonance image data therefrom, is also part of the image data-generating facility 50. This magnetic resonance image data is then optimized with regard to its resolution and the thus generated magnetic resonance image data HBD with increased resolution can then be stored, for example in a memory 119.

The central controller 113 can be operated via a terminal with an input unit 111 and a display unit 109 via which the entire MR system 80 can thus also be operated by one operator. MR images can also be displayed on the display unit 109 and by means of the input unit 111, potentially in combination with the display unit 109, measurements can be planned and started and, in particular, suitable control protocols with suitable measuring sequences can be selected, as explained above, and potentially be modified.

Furthermore, the inventive MR system 80 and, in particular, the controller 113 can also have a large number of further components, not illustrated in detail here but customarily present on such devices, such as a network interface, to connect the entire system to a network and to be able to exchange raw data RD and/or image data BD or parameter maps, but also further data, such as patient-relevant data or control protocols. The controller 113 may include processing circuitry that is adapted to perform one or more functions and/or operations of the controller 113. One or more components of the controller 113 may additionally or alternatively include processing circuitry that is adapted to perform one or more respective functions of the component(s).

How suitable raw data RD can be acquired by irradiating RF pulses and generating gradient fields and how MR images BD can be reconstructed therefrom is basically known to a person skilled in the art and will not be explained in more detail here.

From the above described it will be clear that the disclosure effectively provides possibilities for improving a method for actuating a magnetic resonance imaging system for generating magnetic resonance image data in respect of the required duration.

It should be pointed out that the features of all exemplary embodiments or developments disclosed in figures can be used in any combination.

In conclusion it will once again be pointed out that the detailed methods and the built-on accessories described above are exemplary embodiments and that the basic principle can also be varied in many areas by a person skilled in the art without departing from the scope of the disclosure insofar as it is specified by the claims. For the sake of completeness, it is also pointed out that use of the indefinite article “a” or “an” does not preclude the relevant features from also being present several times. Similarly, the term “unit” does not preclude this from consisting of a plurality of components which can potentially also be spatially distributed. Independent of the grammatical term usage, individuals with male, female or other gender identities are included within the term.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for generating magnetic resonance (MR) image data of an examination object with increased resolution, the method comprising:
sampling k-space data with a non-rectangular sampling pattern, a non-rectangular sampling region of a Cartesian k-space being sampled and a complementary region of the Cartesian k-space being unsampled;
reconstructing first MR image data based on the sampled k-space data; and
generating second MR image data with an increased resolution compared to a resolution of the reconstructed first MR image data by applying a supplementing method, using an artificial intelligence (AI)-based model, the supplementing method being adapted to supplement the reconstructed first MR image data with image information which, transformed into the Fourier domain, is associated with the complementary region determined from the k-space sampling.

2. The method as claimed in claim 1, wherein the complementary region has higher sampling frequencies compared to sampling frequencies of the non-rectangular sampling region, the increased resolution being based on supplementing image information, which is associated with the higher sampling frequencies in the k-space, which lie in the complementary region.

3. The method as claimed in claim 1, wherein the non-rectangular sampling pattern comprises: elliptical sampling; radial sampling; helical sampling; balanced steady state free precession line acquisition with undersampling (BLADE) sampling; and/or Periodically Rotated Overlapping Parallel Lines with Enhanced Reconstruction (PROPELLER) sampling.

4. The method as claimed in claim 1, wherein generating the second MR image data comprises:
generating preliminary second MR image data for generating the data consistency, the preliminary second MR image data being transformed into the Fourier domain, wherein Fourier domain data associated with the preliminary second MR image data is generated;
generating modified Fourier domain data, the Fourier domain data associated with the preliminary second MR image data within the non-rectangular sampling region being modified by a projection of Fourier domain data associated with the first MR image data onto the Fourier domain data associated with the preliminary second MR image data;
transforming the modified Fourier domain data into the image data domain to generate data-consistent second MR image data.

5. The method as claimed in claim 4, wherein the projection comprises a hard projection adapted such that the Fourier domain data associated with the preliminary second MR image data within the non-rectangular sampling region is replaced by the Fourier domain data associated with the first MR image data.

6. The method as claimed in claim 4, wherein the projection comprises a soft projection adapted such that the Fourier domain data associated with the preliminary second MR image data within the non-rectangular sampling region is combined with the Fourier domain data associated with the first MR image data.

7. The method as claimed in claim 1, wherein a dedicated model for the sampling pattern type specifically used for the non-rectangular sampling pattern is utilized as the AI-based model.

8. The method as claimed in claim 1, wherein, as a function of geometry of the non-rectangular sampling pattern, a plurality of image portions formed by a subset of the first MR image data is defined and the supplementing method is applied separately to the respective image portions and the second MR image data generated based on the first MR image data of the respective image portions is combined to form an overall image with increased resolution.

9. The method as claimed in claim 8, wherein the overall image is combined by way of an addition, based on a fade-out, of the second MR image data of mutually overlapping sections of the respective image portions.

10. A non-transitory computer-readable storage medium with an executable program stored thereon, that when executed, instructs a processor to perform the method of claim 1.

11. A method for training an artificial intelligence (AI)-based model for a method for supplementing magnetic resonance (MR) image data with image information, comprising:
generating labeled training data which has input data and validated results data, wherein:
the validated results data comprises reconstructed MR image data from an examination object having been reconstructed based on k-space data obtained by a complete sampling of a Cartesian k-space, and
the input data comprises reconstructed MR image data from the examination object, which was reconstructed based on a subset of the k-space data, wherein the subset of the k-space data is associated with a non-rectangular sampling region of k-space, which was generated by setting the k-space data outside of the non-rectangular sampling region to zero;
applying the AI-based model to be trained with the method for supplementing magnetic resonance image data with image information to the input data to generate results data; and
generating a trained AI-based model by adapting the AI-based model based on the results data and the validated results data.

12. The method as claimed in claim 11, wherein the trained AI-based model is based on a super resolution network.

13. The method as claimed in claim 11, wherein the input data and/or the results data comprises phase images or complex-valued images.

14. A non-transitory computer-readable storage medium with an executable program stored thereon, that when executed, instructs a processor to perform the method of claim 11.

15. An image data-generating device, comprising:
an input interface adapted to receive sampled k-space data with a non-rectangular sampling pattern, wherein a non-rectangular sampling region of a Cartesian k-space is sampled and a complementary region of the Cartesian k-space is unsampled;
a reconstructor adapted to reconstruct first magnetic resonance (MR) image data based on the sampled k-space data;
an image data-generator adapted to generate second MR image data with increased resolution compared to a resolution of the reconstructed first MR image data by applying a supplementing method, which is based on an artificial intelligence (AI)-based model adapted to supplement the reconstructed first MR image data with image information which, transformed into the Fourier domain, is associated with the complementary region determined from the k-space-sampling.

16. A magnetic resonance imaging (MRI) system comprising the image data-generating device as claimed in claim 15.
